(19) United States
(12) Patent Application Publication
(10) Pub. No.: US 2025/0098376 A1
(43) Pub. Date: Mar. 20, 2025

(54) INORGANIC LIGHT EMITTING DIODE AND DISPLAY MODULE INCLUDING THE SAME

(71) Applicant: SAMSUNG ELECTRONICS CO., LTD., Suwon-si (KR)

(72) Inventors: Kihyung KANG, Suwon-si (KR); Kimura SHUNSUKE, Suwon-si (KR)

(73) Assignee: SAMSUNG ELECTRONICS CO., LTD., Suwon-si (KR)

(21) Appl. No.: 18/799,711

(22) Filed: Aug. 9, 2024

Related U.S. Application Data
(63) Continuation of application No. PCT/KR2024/010928, filed on Jul. 26, 2024.

(30) Foreign Application Priority Data
Sep. 18, 2023 (KR) 10-2023-0124233

(51) Int. Cl. H01L 33/50; H01L 25/075; H01L 33/60; H01L 33/62

(52) U.S. Cl. CPC H10H 20/8512; H01L 25/0753; H10H 20/8515; H10H 20/856; H10H 20/857

(57) ABSTRACT

A display module may include a substrate and an inorganic light emitting diode on the substrate. The inorganic light emitting diode includes: an active layer configured to generate light having a first color; a light emitting surface spaced apart from the active layer; a groove part including grooves recessed in the light emitting surface; and a quantum dot (QD) layer in the groove part and configured to convert the light having the first color generated in the active layer into a second color. The display module may further include a color filter corresponding to the inorganic light emitting diode and configured to absorb the light having the first color emitted from the inorganic light emitting diode.

### CROSS-REFERENCE TO RELATED APPLICATIONS

This a bypass continuation application of International Patent Application No. PCT/KR2024/010928, filed on Jul. 26, 2024, which claims priority to Korean Patent Application No. 10-2023-0124233, filed on Sep. 18, 2023, in the Korean Intellectual Property Office, the contents of which are incorporated herein by reference in their entireties.

### BACKGROUND

### 1. Field

Embodiments of the present disclosure relate to an inorganic light emitting diode and a display module including the same.

### 2. Brief Description of Background Art

A display apparatus is a type of output device for visually displaying data information such as characters and figures and images.

In general, liquid crystal panels that require a backlight, or organic light emitting diode (OLED) panels made of a film of organic compounds that emit their own light in response to electric current, are used as display apparatuses. However, the liquid crystal panels have a slow response time, high power consumption, do not emit its own light, and require a backlight, making it difficult for the liquid crystal panels to be compact. Also, the OLED panels do not require a backlight and may be made thinner because the OLED panels emit their own light, but are vulnerable to a burn-in (deterioration) phenomenon in which, when the same image is displayed for a long period of time, certain parts of the previous image remain even when subpixels expire and the image changes. Therefore, as new panels to replace these, micro light emitting diode (microLED or μLED) panels, in which inorganic light emitting diodes are mounted on a substrate and the inorganic light emitting diodes themselves are used as pixels, are being studied.

A micro light emitting diode display panel (hereinafter referred to as microLED panels), which is a type of flat display panels, is composed of a plurality of inorganic light emitting diodes (inorganic LEDs) each measuring less than 100 micrometers.

This type of LED panel has also its own light emitting diodes, but does not cause the burn-in phenomenon of the OLEDs, and has excellent brightness, resolution, power consumption, and durability.

Compared to liquid crystal display (LCD) panels that require a backlight, the microLED display panels offer better contrast, response time, and energy efficiency. Both the organic light emitting diodes (organic LEDs) and the microLEDs have good energy efficiency, but the microLEDs have better brightness, luminous efficiency, and longer lifespan than the OLEDs.

In addition, the LEDs are arranged in pixel units on a circuit substrate, so that modular production of displays in substrate units is possible, and it is easy to produce displays with various resolutions and screen sizes depending on consumer orders.

### SUMMARY

Embodiment of the present disclosure provide an inorganic light emitting diode with improved light efficiency and a display module including the same.

Embodiment of the present disclosure provide an inorganic light emitting diode with improved color conversion efficiency and a display module including the same.

Embodiment of the present disclosure provide an inorganic light emitting diode capable of reducing and/or preventing loss of light and a display module including the same.

Aspects of embodiments of the present disclosure are not limited to the aspects mentioned above, and other aspects not mentioned will be clearly understood by those skilled in the art to which the present disclosure belongs from the description below.

According to embodiments of the present disclosure, a display module is provided and includes a substrate, an inorganic light emitting diode on the substrate, and a color filter corresponding to the inorganic light emitting diode. The inorganic light emitting diode may include an active layer configured to generate light having a first color, a light emitting surface spaced apart from the active layer, a groove part including grooves recessed in the light emitting surface, and a quantum dot (QD) layer in the groove part and configured to convert the light having the first color generated in the active layer into a second color. The color filter may be configured to absorb the light having the first color emitted from the inorganic light emitting diode.

According to embodiments of the present disclosure, an inorganic light emitting diode is provided and includes a first semiconductor including a light emitting surface, a second semiconductor spaced apart from the first semiconductor, an active layer between the first semiconductor and the second semiconductor and configured to generate light, a groove part including a plurality of grooves recessed in the light emitting surface, and a quantum dot (QD) layer inside the groove part. The QD layer may be configured to convert a color of the light generated by the active layer from a first color to a second color.

### BRIEF DESCRIPTION OF DRAWINGS

FIG. 1 illustrates a display apparatus according to an embodiment.

FIG. 2 is an exploded view illustrating components of the display apparatus according to an embodiment.

FIG. 3 is an enlarged cross-sectional view illustrating some components of a display module according to an embodiment.

FIG. 4 is an enlarged cross-sectional view of an inorganic light emitting diode shown in FIG. 3.

FIG. 5 is a cross-sectional view illustrating an example of the inorganic light emitting diode.

FIG. 6 is a cross-sectional view illustrating an example of the inorganic light emitting diode.

FIG. 7 is a cross-sectional view illustrating an example of the inorganic light emitting diode.

FIG. 8 is a cross-sectional view illustrating an example of the inorganic light emitting diode.

FIG. 9 is a cross-sectional view illustrating an example of the inorganic light emitting diode.

FIG. 10 is a cross-sectional view illustrating an example of the inorganic light emitting diode.

FIG. 11 is a cross-sectional view illustrating an example of the inorganic light emitting diode.

FIG. 12 is a cross-sectional view illustrating an example of the inorganic light emitting diode.

FIG. 13 is an enlarged cross-sectional view illustrating an example of the inorganic light emitting diode.

### DETAILED DESCRIPTION

The example embodiments and terms described in the present disclosure are not intended to limit the scope of the present disclosure to specific embodiments, and should be understood to include various modifications, equivalents, and/or substitutes of the example embodiments.

In connection with the description of the drawings, like reference numbers may be used for like or related components.

The singular form of a noun corresponding to an item may include one item or a plurality of items, unless the relevant context clearly dictates otherwise.

In this document, each of phrases such as “A or B,” “at least one of A and B,” “at least one of A or B,” “A, B or C,” “at least one of A, B and C,” and “at least one of A, B, or C” may include any one of the items listed together in the corresponding one of the phrases, or all possible combinations thereof.

The term “and/or” includes any combination of a plurality of related components or any one of a plurality of related components.

The terms “part,” “module,” and “member” may be implemented as hardware or software. Depending on embodiments, a plurality of “parts,” “modules,” and “members” may be implemented as one component, or one “part,” “module,” and “member” may include a plurality of components.

Terms such as “first” and “second,” or “primary” and “secondary” may simply be used to distinguish a given component from other corresponding components, and do not limit the corresponding components in any other aspect (e.g., importance or order).

When any (e.g., first) component is referred to as being “coupled” or “connected” to another (e.g., second) component with or without the term “functionally” or “communicatively,” this means that the any component may be connected to the other component directly (e.g., by wire), wirelessly, or through a third component.

The terms “comprises,” “includes,” and “has” are intended to indicate that there are features, numbers, steps, operations, components, parts, or combinations thereof described in this document, and do not exclude the presence or addition of one or more other features, numbers, steps, operations, components, parts, or combinations thereof.

When any component is referred to as being “connected,” “coupled,” “supported” or “in contact” with another component, this includes a case in which the components are indirectly connected, coupled, supported, or in contact with each other through a third component as well as directly connected, coupled, supported, or in contact with each other.

When any component is referred to as being located “on” or “over” another component, this includes not only a case in which any component is in contact with another component but also a case in which another component is present between the two components.

The meaning of “identical” includes things that have similar properties or are similar within a certain range. Also, the “identical” means “substantially identical.” The meaning of “substantially identical” should be understood as falling within the scope of “identical” as a value that falls within a margin of error in manufacturing or a value that corresponds to a difference within a range that has no meaning with respect to a reference value.

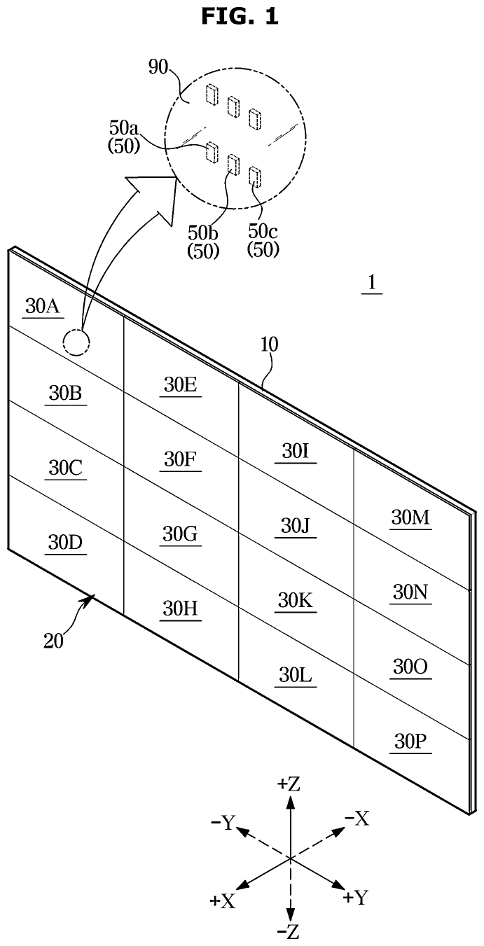

The expressions related to directions used in the following description, such as terms “front,” “rear,” “left,” “right,” “upper,” and “lower” are defined based on the drawings, and the shape and location of each component are not limited by these terms. For example, a direction in which an image is displayed based on a display apparatus 1 shown in FIG. 1 may be defined as the front (+X direction), and a side opposite to the front may be defined as the rear (−X direction). For example, the front (+X direction) may be substantially the same as a light emitting direction of each of a plurality of inorganic light emitting diodes.

In the drawings, some components of the display apparatus 1, including a plurality of inorganic light emitting diodes 50, are micro-scale components having a size of several um to hundreds of μm, and for convenience of explanation, the scales of some components (e.g., a plurality of inorganic light emitting diodes 50, anisotropic conductive layer 60, color filter 70, black matrix 80, etc.) may be exaggerated.

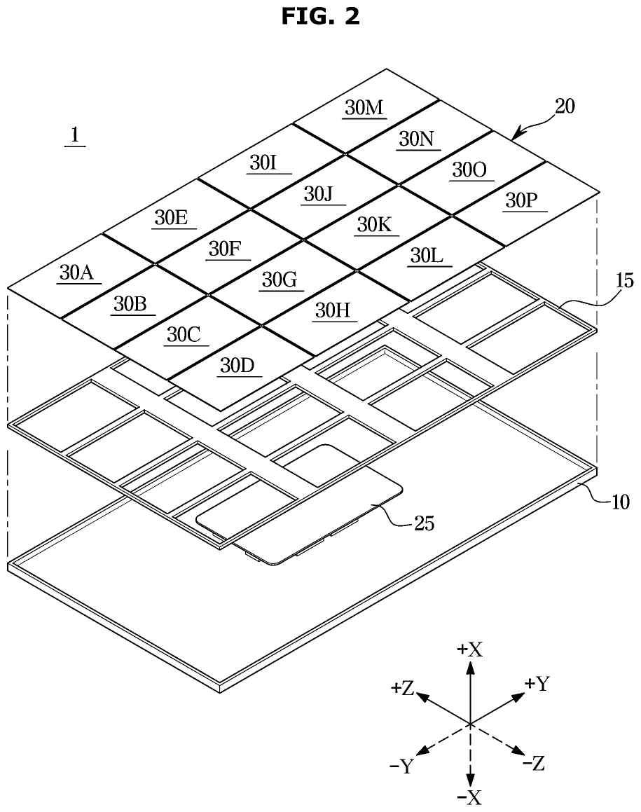

FIG. 1 illustrates a display apparatus according to an embodiment. FIG. 2 is an exploded view illustrating components of the display apparatus according to an embodiment.

A display apparatus 1 is a device that displays information, materials, data, and the like in the form of text, shapes, graphs, images, and the like, and a television (TV), a personal computer (PC), a mobile device, digital signage, and the like may be implemented as the display apparatus 1.

The display apparatus 1 may include a display panel 20 provided to display an image. The display apparatus 1 may include a power supply device provided to supply power to the display panel 20. The display apparatus 1 may include a main board 25 provided to control the overall operation of the display panel 20.

The display panel 20 may be provided to display an image on a front surface thereof. The display panel 20 may include a plurality of inorganic light emitting diodes 50. A detailed description of the plurality of inorganic light emitting diodes 50 will be provided later.

The display panel 20 may include a plurality of display modules 30A-30P. The display panel 20 may include a driving board to drive each of the display modules 30A-30P. The display panel 20 may include a timing controller board (TOCN board) to generate a timing signal for controlling each of the display module 30A-30P.

The plurality of display modules 30A-30P may be arranged up, down, left and right so as to be adjacent to each other. The plurality of display modules 30A-30P may be arranged in an M*N matrix. FIGS. 1 and 2 illustrate that a plurality of display modules 30A-30P is provided in the number of sixteen and arranged in the form of a 4*4 matrix, but there is no limit to the number and arrangement of the plurality of display modules.

The display apparatus 1 may be implemented as a large screen by tiling the plurality of display modules 30A-30P.

As illustrated in FIGS. 1 and 2, the plurality of display modules 30A-30P, which is a matrix type, may be applied to a display apparatus such as monitors for personal computers (PCs), high-resolution TVs, signages, electronic displays, through a plurality of assembly arrangements.

Unlike what is illustrated in FIGS. 1 and 2, in the plurality of display modules 30A-30P, each single display module may be applied to a display apparatus. That is, the display modules 30A-30P may be installed and applied as a single unit to wearable devices, portable devices, handheld devices, and various electronic products or electronic devices that include displays. For example, the display panel 20 may include one display module.

For example, each of the display modules 30A-30P may be formed in a quadrangle type. For example, each of the display modules 30A-30P may be provided in a rectangle type shape or a square type shape.

For example, the plurality of display modules 30A-30P may be installed on a frame 15. The plurality of display modules 30A-30P may be installed on the frame 15 through various methods, such as a magnetic force using a magnet and a mechanical fitting structure. For example, the frame 15 may be provided as one component of a case 10, which will be described later.

The plurality of display modules 30A-30P may have the same configuration as each other. Therefore, the description of one display module described below may be equally applied to all other display modules.

The display apparatus 1 may include the case 10. The case 10 may support the display panel 20. The case 10 may accommodate at least a portion of the display panel 20. The case 10 may cover the rear of the display panel 20. The case 10 may form a rear exterior of the display apparatus 1.

For example, the case 10 may be installed on a floor by a stand, or may be installed on a wall by a hanger.

For example, the case 10 may be provided in the form of an assembly in which a plurality of components are combined.

For example, the case 10 may include a metal material. Accordingly, heat generated in the display panel 20 may be easily conducted to the case 10 to increase heat dissipation efficiency of the display apparatus 1.

The case 10 may be referred to as a chassis, mold, rear cover, etc.

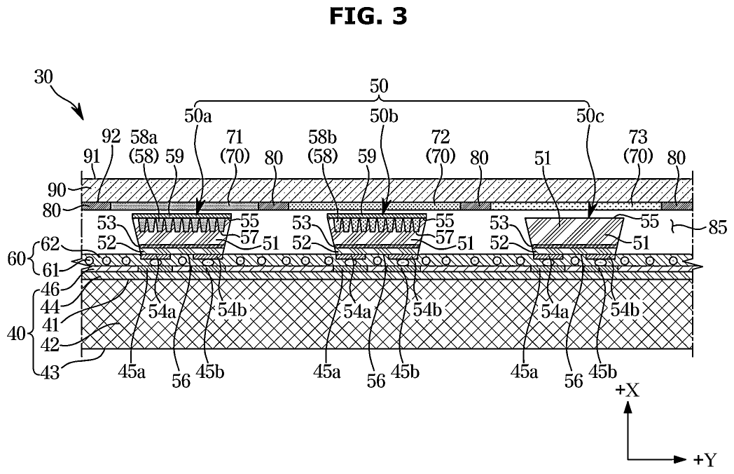

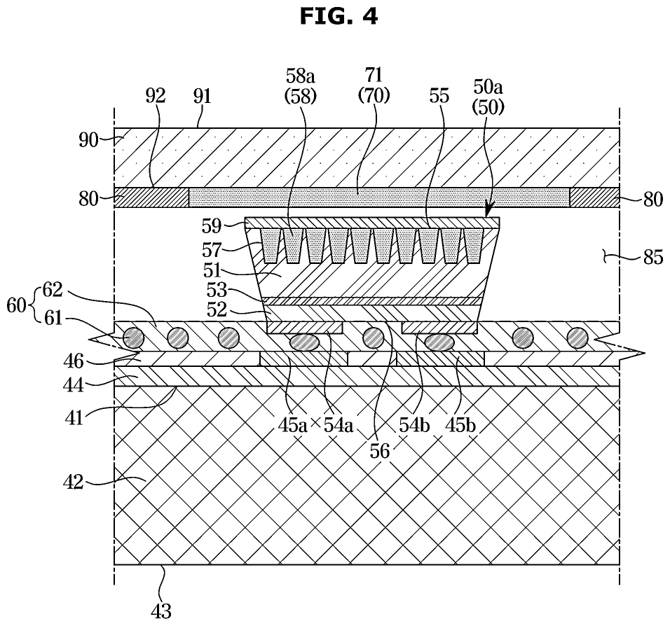

FIG. 3 is an enlarged cross-sectional view illustrating some components of a display module according to an embodiment. FIG. 4 is an enlarged cross-sectional view of an inorganic light emitting diode shown in FIG. 3.

Hereinafter, a description of the display module 30 corresponds to a description of any one of the plurality of display modules 30A-30P. Accordingly, the description of the display module 30 may be applied to each of the plurality of display modules 30A-30P. Likewise, descriptions of the components of the display module 30 may be applied to components of each of the plurality of display modules 30A-30P. In addition, hereinafter, a description of the inorganic light emitting diode 50, which is a description of any one of a plurality of the inorganic light emitting diodes 50, corresponds to a description of common features of the plurality of inorganic light emitting diodes 50. That is, the description of the inorganic light emitting diode 50 may be applied to each of the plurality of inorganic light emitting diodes 50.

Referring to FIGS. 3 and 4, the display module 30 may include a substrate 40 and the plurality of inorganic light emitting diodes 50 mounted on the substrate 40. The plurality of inorganic light emitting diodes 50 may be mounted on a mounting surface 41 side of the substrate 40 facing in a first direction (+X direction). FIGS. 3 and 4 illustrate that a thickness of the substrate 40 in the first direction (+X direction) is exaggeratedly thick for convenience of explanation.

The substrate 40 may be provided to support the plurality of inorganic light emitting diodes 50. The substrate 40 may be electrically connected to the plurality of inorganic light emitting diodes 50. For example, the substrate 40 may be provided to control each of the plurality of inorganic light emitting diodes 50. For example, the substrate 40 may enable communication between the plurality of inorganic light emitting diodes 50.

For example, the substrate 40 may be implemented with various substrates such as a thin film transistor (TFT) substrate, a printed circuit board (PCB) substrate, a flexible printed circuit board (FPCB) substrate, and a complementary metal oxide semiconductor (CMOS) substrate. For example, the substrate 40 may include various components such as pad electrodes, wiring, and circuit elements. However, embodiments of the present disclosure are not limited to the above-described examples, and the substrate 40 may be provided as various types of substrates as long as the substrate may be electrically connected to the plurality of inorganic light emitting diodes 50.

As described above, each of the plurality of display modules 30A-30P may be provided in a quadrangle shape, and the substrate 40 may be formed in a quadrangle type to correspond thereto. For example, the substrate 40 may be provided in a rectangular shape or a square shape.

The substrate 40 may include a substrate body 42. The substrate body 42 may include the mounting surface 41 on which the plurality of inorganic light emitting diodes 50 is mounted. The mounting surface 41 may be provided as one surface of the substrate body 42. The substrate body 42 may include a rear surface 43 formed on the opposite side of the substrate body 42 from the mounting surface 41. The rear surface 43 may be provided as the other surface of the substrate body 42.

The mounting surface 41 may be provided to face the plurality of inorganic light emitting diodes 50. The mounting surface 41 may be provided to face a cover 90, which will be described later. The mounting surface 41 may be provided to face a black matrix 80, which will be described later. The mounting surface 41 may be provided to face a color filter 70, which will be described later. The rear surface 43 may be provided to face the case 10.

For example, the substrate body 42 may include a glass substrate. For example, the substrate body 42 may be made of a silicon wafer. However, embodiments of the present disclosure are not limited to the above-described examples, and the substrate body 42 may have various materials.

The substrate 40 may include a driving layer 44. The driving layer 44 may be provided to drive the plurality of inorganic light emitting diodes 50. The driving layer 44 may be provided to drive each of the plurality of inorganic light emitting diodes 50. The driving layer 44 may be provided to individually drive the plurality of inorganic light emitting diodes 50. The driving layer 44 may be formed on the substrate body 42. The driving layer 44 may be formed on one side of the substrate body 42. The driving layer 44 may be formed on the mounting surface 41 of the substrate body 42.

For example, the driving layer 44 may include a thin film transistor (TFT). For example, the driving layer 44 may include at least one from among a low temperature poly silicon (LTPS) TFT, an oxide TFT, an amorphous-silicon TFT, a zinc oxide TFT, an organic TFT, and a graphene TFT. However, embodiments of the present disclosure are not limited to the above-described examples, and the TFT constituting the driving layer 44 is not limited to a specific structure or type and may have various configurations. When the driving layer 44 includes the TFT, the driving layer 44 may be referred to as a TFT layer.

For example, when the substrate body 42 of the substrate 40 is made of a silicon wafer, the driving layer 44 may be replaced with a complementary metal-oxide semiconductor (CMOS) type or n-type MOSFET or p-type MOSFET transistor.

The substrate 40 may include a first pad electrode 45a and a second pad electrode 45b. The first pad electrode 45a and the second pad electrode 45b may be formed on the mounting surface 41 side of the substrate 40. The first pad electrode 45a and the second pad electrode 45b may be electrically connected to the driving layer 44. The first pad electrode 45a and the second pad electrode 45b may be provided to correspond to a first contact electrode 54a and a second contact electrode 54b, respectively, which will be described later. As the first pad electrode 45a and the second pad electrode 45b are electrically connected to the first contact electrode 54a and the second contact electrode 54b, respectively, the inorganic light emitting diode 50 and the driving layer 44 may be electrically connected.

The substrate 40 may further include a light absorbing layer 46 to improve contrast by absorbing external light. The light absorbing layer 46 may be provided on the mounting surface 41 of the substrate 40. For example, the light absorbing layer 46 may be provided between the driving layer 44 and an anisotropic conductive layer 60, which will be described later.

The plurality of inorganic light emitting diodes 50 may be formed of an inorganic material and may include the inorganic light emitting diodes 50 having a width, length, and height of several μm to tens of μm, respectively. For example, the inorganic light emitting diode 50 may have a short side length of 100 μm or less among the width, length, and height. For example, the inorganic light emitting diode 50 may be picked up from a sapphire or silicon wafer and transferred to the substrate 40. For example, the inorganic light emitting diode 50 may be picked up and transported through various methods, such as an electrostatic method using an electrostatic head or a stamp method using an elastic polymer material such as polydimethylsiloxane (PDMS) or silicon as a head. However, embodiments of the present disclosure are not limited to the above-described examples, and the inorganic light emitting diode 50 may be mounted on the substrate 40 through various methods.

The inorganic light emitting diode 50 may include an active layer 53 to generate light. Light generated in the active layer 53 may have a first color. The active layer 53 may include a material that emits light by recombination of electrons and holes. The active layer 53 may be disposed between a first semiconductor 51 and a second semiconductor 52, which will be described later. The active layer 53 may be formed between the first semiconductor 51 and the second semiconductor 52, which will be described later.

For example, the active layer 53 may generate light of various colors depending on the material of the inorganic light emitting diode 50. For example, when the inorganic light emitting diode 50 includes gallium nitride (GaN), the active layer 53 may emit blue light. However, embodiments of the present disclosure are not limited to the above-described example. The inorganic light emitting diode 50 may include various materials, and accordingly, the active layer 53 may generate light of various colors.

The inorganic light emitting diode 50 may include the first semiconductor 51 and the second semiconductor 52. The first semiconductor 51 and the second semiconductor 52 may be disposed with the active layer 53 interposed therebetween. The second semiconductor 52 may be spaced apart from the first semiconductor 51. For example, the first semiconductor 51 may include a light emitting surface 55, which will be described later. For example, the second semiconductor 52 may include a bottom surface 56, which will be described later. However, embodiments of the present disclosure are not limited thereto. For example, a protective layer may be provided on the first semiconductor 51, and the protective layer provided on the first semiconductor 51 may include the light emitting surface 55.

One from among the first semiconductor 51 and the second semiconductor 52 may be an n-type semiconductor, and the other from among the first semiconductor 51 and the second semiconductor 52 may be a p-type semiconductor. Electrons may exist in one from among the first semiconductor 51 and the second semiconductor 52, and holes may exist in the other one from among the first semiconductor 51 and the second semiconductor 52. Light may be generated while these electrons and holes recombine in the active layer 53.

The inorganic light emitting diode 50 may include the light emitting surface 55. The inorganic light emitting diode 50 may include the bottom surface 56 disposed on the opposite side of the inorganic light emitting diode 50 from the light emitting surface 55.

The light emitting surface 55 may be spaced apart from the active layer 53. When the inorganic light emitting diode 50 is mounted on the substrate 40, the light emitting surface 55 may be disposed toward the first direction (+X direction). The light emitting surface 55 may be disposed to face the color filter 70. The light emitting surface 55 may diffuse light toward the color filter 70. The light emitting surface 55 may diffuse light toward the cover 90.

The inorganic light emitting diode 50 may include the first contact electrode 54a and the second contact electrode 54b. The first contact electrode 54a and the second contact electrode 54b may be provided to correspond to the first pad electrode 45a and the second pad electrode 45b, respectively. The first contact electrode 54a and the second contact electrode 54b may be electrically connected to the first pad electrode 45a and the second pad electrode 45b, respectively. Accordingly, the inorganic light emitting diode 50 and the driving layer 44 of the substrate 40 may be electrically connected.

According to embodiments of the present disclosure, one from among the first contact electrode 54a and the second contact electrode 54b may be electrically connected to the first semiconductor 51, and the other one from among the first contact electrode 54a and the second contact electrode 54b may be electrically connected to the second semiconductor 52.

The first contact electrode 54a and the second contact electrode 54b may be formed on the opposite side (e.g., the bottom surface 56) of the inorganic light emitting diode 50 from the light emitting surface 55. The first contact electrode 54a and the second contact electrode 54b may be disposed to face a direction (−X direction) opposite to a direction in which light is irradiated (+X direction). The first contact electrode 54a and the second contact electrode 54b may be disposed to face the substrate 40.

Accordingly, when light is irradiated toward the color filter 70 through the light emitting surface 55, the light may be irradiated without interference with the first contact electrode 54a and/or the second contact electrode 54b.

For example, the first contact electrode 54a and the second contact electrode 54b may be in the form of a flip chip disposed horizontally and facing the same direction (a direction opposite of the light emission direction).

The display module 30 may include the anisotropic conductive layer 60 provided to electrically connect the inorganic light emitting diode 50 and the substrate 40. The anisotropic conductive layer 60 may electrically connect the inorganic light emitting diode 50 and the driving layer 44. The anisotropic conductive layer 60 may electrically connect the first contact electrode 54a and the second contact electrode 54b of the inorganic light emitting diode 50 to the first pad electrode 45a and the second pad electrode 45b of the substrate 40.

The anisotropic conductive layer 60, which is formed by attaching an anisotropic conductive adhesive onto a protective film, may have a structure in which conductive balls 61 are dispersed in an adhesive resin 62. The conductive ball 61, which is a conductive sphere surrounded by a thin insulating film, may electrically connect one conductor to another as the insulating film is broken by pressure.

For example, the anisotropic conductive layer 60 may be provided as an anisotropic conductive film (ACF) in the form of a film. For example, the anisotropic conductive layer 60 may be provided as an anisotropic conductive paste (ACP) in the form of a paste.

However, embodiments of the present disclosure are not limited to the above-described examples, and various adhesion methods may be used to electrically connect the inorganic light emitting diode 50 and the substrate 40. As an example, the anisotropic conductive layer 60 may be replaced with various adhesive components such as solder.

The display module 30 may include the color filter (CF) 70. The color filter 70 may be provided to correspond to the inorganic light emitting diode 50. The inorganic light emitting diode 50 may irradiate light toward the color filter 70. For example, the color filter 70 may be provided in a plurality of configurations, or may be provided in a single configuration including a plurality of filter areas each corresponding to various colors. A detailed description of the color filter 70 will be provided later.

The display module 30 may include the black matrix (BM) 80. The black matrix 80 may have colors in black tones. For example, the black matrix 80 may be disposed between a plurality of color filters, or may be provided as a single component of the color filter 70 and disposed between the plurality of filter areas. A detailed description of the black matrix 80 will be provided later.

The display module 30 may include the cover 90. The cover 90 may include a first cover surface 91. The cover 90 may include a second cover surface 92 formed on the opposite side of the cover 90 from the first cover surface 91. The first cover surface 91 may form a front surface of the display module 30. The second cover surface 92 may be provided to face the plurality of inorganic light emitting diodes 50. The first cover surface 91 of the cover 90 may be referred to as the front surface of the cover 90, and the second cover surface 92 of the cover 90 may be referred to as the rear surface of the cover 90.

Light emitted from the plurality of inorganic light emitting diodes 50 may be incident on the cover 90 through the second cover surface 92, and the light incident on the cover 90 may be emitted to the outside in front of the display module 30 through the first cover surface 91.

The cover 90 may be provided to cover the plurality of inorganic light emitting diodes 50. The cover 90 may protect the plurality of inorganic light emitting diodes 50. For example, the cover 90 may protect the plurality of inorganic light emitting diodes 50 from external force, external moisture, external foreign substances, etc.

The cover 90 may be provided to cover the substrate 40. The cover 90 may protect the substrate 40. For example, the cover 90 may protect the substrate 40 from external force, external moisture, external foreign substances, etc.

For example, the cover 90 may include glass. For example, the cover 90 may include a functional film having optical performance. For example, the cover 90 may be provided with a plurality of layers. However, embodiments of the present disclosure are not limited to the above-described examples, and the cover 90 may include various materials and/or structures.

A structure and/or arrangement of pixels of the display module 30 will be described below with reference to FIGS. 3 and 4. Hereinafter, for convenience of explanation, the inorganic light emitting diode 50 including an active layer 53 to generate blue light will be described as an example.

The plurality of inorganic light emitting diodes 50 may include a red light emitting diode 50a, a green light emitting diode 50b, and a blue light emitting diode 50c. A series of the red light emitting diode 50a, green light emitting diode 50b, and blue light emitting diode 50c may be mounted on the substrate 40 as one unit. The series of the red light emitting diode 50a, green light emitting diode 50b, and blue light emitting diode 50c may form one pixel. In this case, the red light emitting diode 50a, green light emitting diode 50b, and blue light emitting diode 50c may each form a subpixel.

For example, the red light emitting diode 50a, green light emitting diode 50b, and blue light emitting diode 50c may be arranged in a line. For example, the green light emitting diode 50b may be spaced apart from the red light emitting diode 50a. For example, the blue light emitting diode 50c may be spaced apart from the green light emitting diode 50b. For example, the red light emitting diode 50a, green light emitting diode 50b, and blue light emitting diode 50c may be arranged in a different form from the form shown in the drawing, such as a triangular shape.

The red light emitting diode 50a, green light emitting diode 50b, and blue light emitting diode 50c may be referred to as a first inorganic light emitting diode, a second inorganic light emitting diode, and a third inorganic light emitting diode, respectively. However, the ordinal numbers “first,” “second,” and “third” do not limit the components.

Some parts of the plurality of inorganic light emitting diodes 50 may have a different structure from other parts of the plurality of inorganic light emitting diodes 50. For example, a structure of the blue light emitting diode 50c may be different from a structure of the red light emitting diode 50a. For example, the structure of the blue light emitting diode 50c may be different from a structure of the green light emitting diode 50b.

The blue light emitting diode 50c may emit light generated in the active layer 53 without converting its color. The blue light emitting diode 50c may emit blue light.

Each of the red light emitting diode 50a and green light emitting diode 50b may convert the color of light generated in its active layer 53 and emit the converted light. For example, the red light emitting diode 50a may convert blue light into red light. For example, the green light emitting diode 50b may convert blue light into green light. The inorganic light emitting diode 50 capable of converting the color of light generated in the active layer 53, such as the red light emitting diode 50a and the green light emitting diode 50b, may be referred to as a color conversion element. The color conversion element, which corresponds to an example of the inorganic light emitting diode 50, may be referred to as the inorganic light emitting diode 50. An example of the inorganic light emitting diode 50 capable of color conversion will be described below.

The inorganic light emitting diode 50 may include a groove part 57 formed at the light emitting surface 55. The groove part 57 may be recessed in the light emitting surface 55. The groove part 57 may include a plurality of grooves. The groove part 57 may include one or more grooves. For example, the groove part 57 may be formed by etching.

For example, the groove part 57 may be formed on the first semiconductor 51, and a depth of each of the plurality of grooves may be smaller than a thickness of the first semiconductor 51.

As the inorganic light emitting diode 50 includes the groove part 57, light efficiency of the inorganic light emitting diode 50 may be improved. For example, when light generated in the active layer 53 is irradiated to the groove part 57, it may not be easy for the light to be totally reflected. That is, a rate at which light generated in the active layer 53 is totally reflected and extinguished inside the inorganic light emitting diode 50 may be reduced, and a light extraction ratio of the inorganic light emitting diode 50 may be increased.

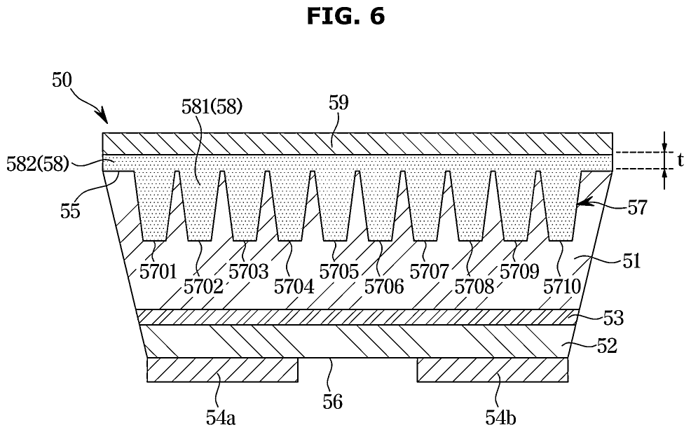

The inorganic light emitting diode 50 may include a quantum dot (QD) layer 58 provided in the groove part 57. The QD layer 58 may be disposed within the groove part 57. The QD layer 58 may be filled inside the groove part 57. The QD layer 58 may be provided to cover the groove part 57. The QD layer 58 may be provided to cover the light emitting surface 55. The QD layer 58 may be provided to cover the groove part 57 and the light emitting surface 55 (see FIGS. 6, 8, 10, and 12).

The QD layer 58 may be provided to convert light having the first color generated in the active layer 53 into light having a second color. The QD layer 58 may be provided to convert the color of light generated in the active layer 53 from the first color to the second color. The second color corresponds to a color different from the first color. That is, the light generated in the active layer 53 may be color converted while passing through the QD layer 58. The QD layer 58 may include quantum dots. The color to be converted may vary depending on a size of the quantum dots of the QD layer 58.

For example, the red light emitting diode 50a may include a QD layer 58a capable of converting blue light into red light. The green light emitting diode 50b may include a QD layer 58b capable of converting blue light into green light. A quantum dot size of the QD layer 58a of the red light emitting diode 50a may be different from a quantum dot size of the QD layer 58b of the green light emitting diode 50b. For example, the quantum dot size of the QD layer 58a of the red light emitting diode 50a may be larger than the quantum dot size of the QD layer 58b of the green light emitting diode 50b.

As the inorganic light emitting diode 50 includes the QD layer 58, color conversion efficiency of the inorganic light emitting diode 50 may be improved. The inorganic light emitting diode 50 may emit various colors through the QD layer 58. The inorganic light emitting diode 50 may emit various colors by varying a type of the QD layer 58.

However, the QD layer 58 may be replaced with a configuration of including a color conversion material other than the quantum dots so that the color of light generated in the active layer 53 may be converted. That is, the description of the QD layer 58 described above (excluding quantum dots) may also be applied to the replaced configuration of the QD layer 58. The QD layer 58 may be referred to as a color conversion layer.

The inorganic light emitting diode 50 may include a dichroic filter 59. The dichroic filter 59 may be provided to cover the light emitting surface 55. The dichroic filter 59 may be provided to cover the QD layer 58. The dichroic filter 59 may be provided to cover the light emitting surface 55 and the QD layer 58.

The dichroic filter 59 may be provided to reflect light having a predetermined wavelength range. The dichroic filter 59 may be provided to reflect light having the first color emitted through at least one from among the light emitting surface 55 and the QD layer 58. The dichroic filter 59 may reflect light having the first color among the light emitted through at least one from among the light emitting surface 55 and the QD layer 58. The dichroic filter 59 may transmit light having the second color among the light emitted through at least one from among the light emitting surface 55 and the QD layer 58. For example, the dichroic filter 59 may include a plurality of layers with different refractive indices.

Light of the first color generated in the active layer 53 may be converted to the second color while passing through the QD layer 58, but may not be converted to the second color by 100% even though passed through the QD layer 58. Also, the light of the first color generated in the active layer 53 may be emitted through the light emitting surface 55 without passing through the QD layer 58. Accordingly, light having the first color may be emitted from at least one from among the light emitting surface 55 and the QD layer 58. Light having the first color may escape from at least one from among the light emitting surface 55 and the QD layer 58.

The dichroic filter 59 may recycle light that has not been color converted by reflecting light having the first color emitted from the light emitting surface 55 and/or the QD layer 58. That is, light having the first color emitted from the light emitting surface 55 and/or the QD layer 58 may be reflected by the dichroic filter 59. Light reflected by the dichroic filter 59 may pass through the QD layer 58. The dichroic filter 59 may allow light that has passed through the QD layer 58 but not color-converted to pass through the QD layer 58 again. The dichroic filter 59 may allow light that has not been color converted by failing to pass through the QD layer 58 to pass through the QD layer 58. The dichroic filter 59 may reduce and/or remove noise of light emitted from the inorganic light emitting diode 50. The dichroic filter 59 may improve the color conversion efficiency of the inorganic light emitting diode 50. Color reproduction of the display module 30 may be excellent.

For example, the dichroic filter 59 of the red light emitting diode 50a may reflect blue light. For example, the dichroic filter 59 of the red light emitting diode 50a may transmit red light.

For example, the dichroic filter 59 of the green light emitting diode 50b may reflect blue light. For example, the dichroic filter 59 of the green light emitting diode 50b may transmit green light.

Although it has been previously described that the dichroic filter 59 is a component of the inorganic light emitting diode 50, embodiments of the present disclosure are not limited thereto. The dichroic filter 59 may be provided as a separate component from the inorganic light emitting diode 50 and may be disposed on a light emitting side of the inorganic light emitting diode 50.

The color filter 70 may be disposed to correspond to the inorganic light emitting diode 50. The color filter 70 may be disposed to face the light emitting surface 55 of the inorganic light emitting diode 50. The color filter 70 may be disposed to face the dichroic filter 59.

The color filter 70 may be provided to absorb light having a predetermined wavelength range. The color filter 70 may be provided to absorb light having the first color emitted from the inorganic light emitting diode 50. The color filter 70 may absorb light having the first color among the light emitted from the inorganic light emitting diode 50. The color filter 70 may pass light having the second color among the light emitted from the inorganic light emitting diode 50.

Light of the first color generated in the active layer 53 may be converted to the second color while passing through the QD layer 58. Light of the first color generated in the active layer 53 may be recycled by the dichroic filter 59 and may be color converted while passing through the QD layer 58. However, the light generated in the active layer 53 may be emitted without passing through the QD layer 58 and may be emitted in a state of not being color converted by 100% even though passed through the QD layer 58 at least once. Accordingly, light of the first color that has not been color converted may be emitted from the inorganic light emitting diode 50. That is, light having the first color may escape from the inorganic light emitting diode 50.

The color filter 70 may absorb light that has not been color converted from the light emitted from the inorganic light emitting diode 50. The color filter 70 may prevent the light that has not been color converted from being irradiated to the cover 90. The color filter 70 may allow only the color-converted light to be irradiated to the cover 90. As a result, the color filter 70 may reduce and/or remove noise of light emitted from the inorganic light emitting diode 50. The color filter 70 may improve color conversion efficiency of the display module 30. The color reproduction of the display module 30 may be excellent.

The display module 30 may include a red filter 71 corresponding to the red light emitting diode 50a. The red filter 71 may be disposed to face the light emitting surface 55 of the red light emitting diode 50a. The red filter 71 may be provided to transmit red light emitted from the red light emitting diode 50a. The red filter 71 may be provided to absorb light outside a wavelength range of red light. For example, the red filter 71 may absorb blue light emitted from the red light emitting diode 50a.

The display module 30 may include a green filter 72 corresponding to the green light emitting diode 50b. The green filter 72 may be disposed to face the light emitting surface 55 of the green light emitting diode 50b. The green filter 72 may be provided to transmit green light emitted from the green light emitting diode 50b. The green filter 72 may be provided to absorb light outside a wavelength range of green light. For example, the green filter 72 may absorb blue light emitted from the green light emitting diode 50b.

The display module 30 may include a blue filter 73 corresponding to the blue light emitting diode 50c. The blue filter 73 may be disposed to face the light emitting surface 55 of the blue light emitting diode 50c. The blue filter 73 may be provided to transmit blue light emitted from the blue light emitting diode 50c. The blue filter 73 may be provided to absorb light outside a wavelength range of blue light.

The red filter 71, green filter 72, and blue filter 73 may be provided as separate color filters, or at least some from among the red filter 71, green filter 72, and blue filter 73 may be provided as integrated color filters. As an example, the color filter 70 may be provided as one layer, and the red filter 71, the green filter 72, and the blue filter 73 may also be provided as the filter area through which red light transmits, the filter area through which green light transmits, and the filter area through which blue light transmits, respectively.

The red filter 71, the green filter 72, and the blue filter 73 may be referred to as a first color filter, a second color filter, and a third color filter, respectively. However, the ordinal numbers “first,” “second,” and “third” do not limit the components.

The black matrix 80 may be provided between a plurality of the color filters. The black matrix 80 may be provided between a plurality of color filter areas of the color filter. The black matrix 80 may be provided between the red filter 71 and the green filter 72. The black matrix 80 may be provided between the green filter 72 and the blue filter 73. According to embodiments of the present disclosure, the black matrix 80 may be provided between the red filter 71 and the blue filter 73.

The black matrix 80 may be provided to partition the red filter 71 and the green filter 72. The black matrix 80 may be provided to partition the green filter 72 and the blue filter 73. According to embodiments of the present disclosure, the black matrix 80 may be provided to partition the red filter 71 and the blue filter 73.

According to embodiments of the present disclosure, for example, the black matrix 80 may be formed between pixels formed by the red light emitting diode 50a, the green light emitting diode 50b, and the blue light emitting diode 50c. According to embodiments of the present disclosure, for example, the black matrix 80 may be disposed to partition each of the light emitting diodes (e.g., the red light emitting diode 50a, the green light emitting diode 50b, and the blue light emitting diode 50c), which are subpixels.

The black matrix 80 may block light to prevent light from escaping between the color filters (or color filter areas). The black matrix 80 may distinguish the respective areas in which light is emitted by subpixels from another area. The black matrix 80 may allow light emitted from the subpixel to be irradiated to an accurate location. Accordingly, the display module 30 may implement a clear screen.

The black matrix 80 may perform a function of complementing the light absorbing layer 46. The black matrix 80 may absorb external light to make the substrate 40 appear black. The black matrix 80 may improve a contrast on the screen of the display module 30.

Embodiments of the present disclosure are not limited to the examples described above with reference to FIGS. 3 and 4. Depending on a type of the inorganic light emitting diode 50, the structure and/or arrangement of the pixels of the display module 30 may be provided in various ways. For example, in a case of being based on the inorganic light emitting diode 50 including the active layer 53 generating red light, the red light emitting diode 50a may not include the groove part 57 and the QD layer 58a, the QD layer 58b of the green light emitting diode 50b may include quantum dots for converting red light into green light, and the blue light emitting diode 50c may include the groove part 57 and the QD layer 58 provided in the groove part 57 to convert red light into blue light. For example, at least some of the respective active layers 53 of the red light emitting diode 50a, green light emitting diode 50b, and blue light emitting diode 50c may be provided to generate light of different colors, and based on this, a configuration and/or structure of each of the red light emitting diode 50a, green light emitting diode 50b, and blue light emitting diode 50c may also vary.

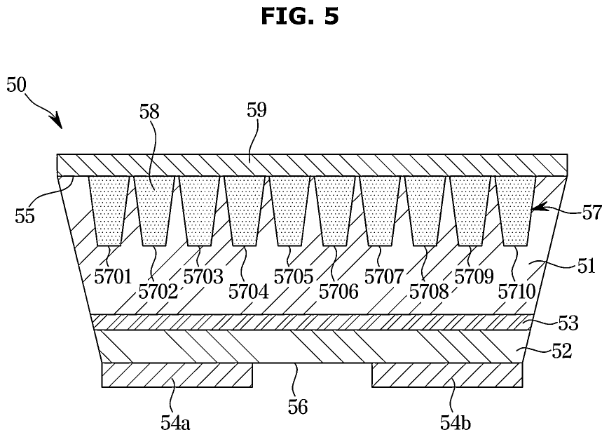

Various examples of the inorganic light emitting diode 50 will be described below with reference to FIGS. 5 to 12.

The groove part 57 may include grooves 5701, 5702, 5703, 5704, 5705, 5706, 5707, 5708, 5709, and 5710 continuously formed in the light emitting surface 55. The groove part 57 may include a plurality of the grooves 5701, 5702, 5703, 5704, 5705, 5706, 5707, 5708, 5709, and 5710 recessed in the light emitting surface 55. For example, the plurality of grooves may be formed in the light emitting surface 55. For example, the plurality of grooves may be formed in a kind of pattern in the light emitting surface 55. For example, the plurality of grooves may be provided in a regular or irregular pattern in the light emitting surface 55. For example, the plurality of grooves may be arranged along a direction (Y direction) substantially intersecting a direction in which the inorganic light emitting diode 50 emits light. For example, the plurality of grooves may be disposed to be spaced apart from each other. For example, at least some of the plurality of grooves may be provided to be in contact with each other rather than being spaced apart from each other.

The drawings illustrate that the number of the grooves 5701, 5702, 5703, 5704, 5705, 5706, 5707, 5708, 5709, and 5710 is ten, but embodiments of the present disclosure are not limited thereto. The inorganic light emitting diode 50 may have nine or fewer grooves or eleven or more grooves. The number of the plurality of grooves is not limited.

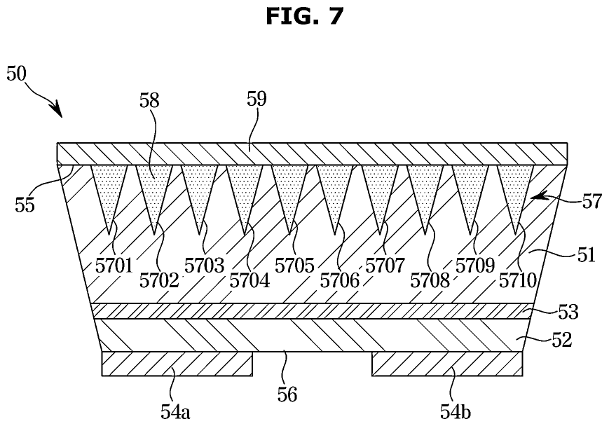

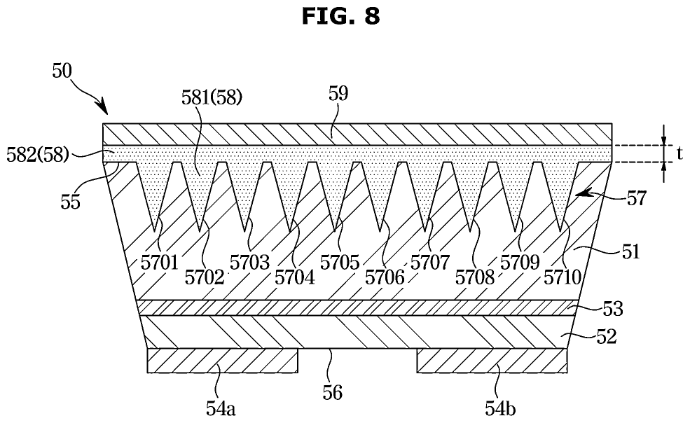

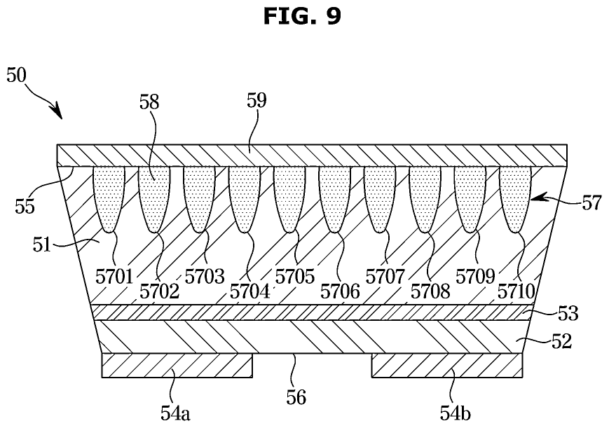

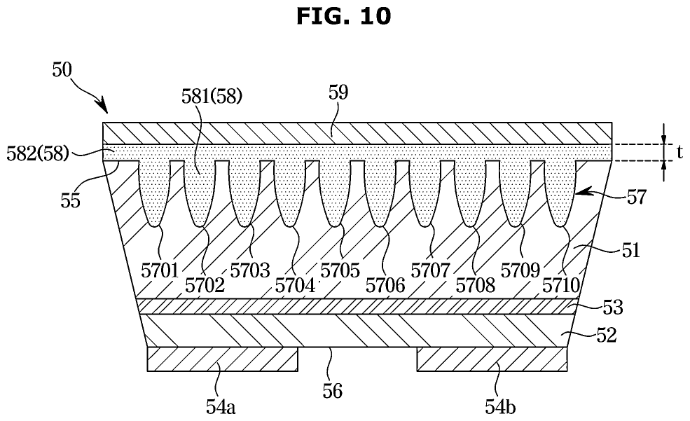

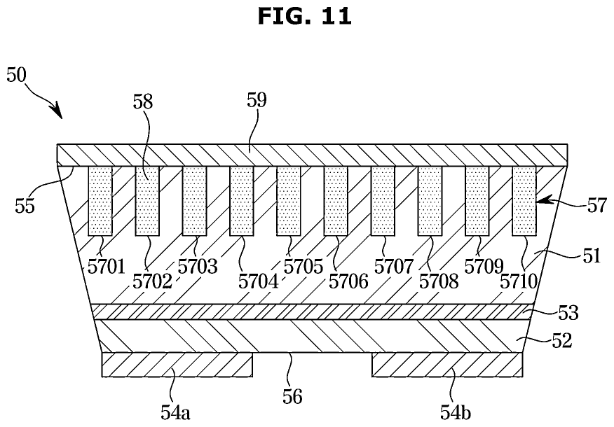

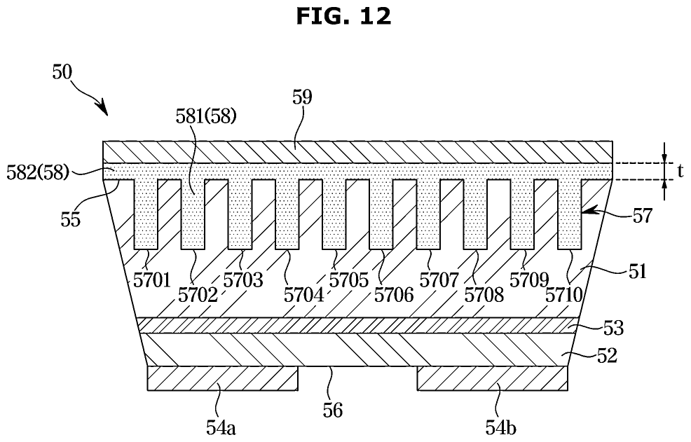

The groove part 57 may include grooves of various shapes. For example, referring to FIGS. 5 and 6, the plurality of grooves 5701, 5702, 5703, 5704, 5705, 5706, 5707, 5708, 5709, and 5710 may have a trapezoidal cross-section. For example, referring to FIGS. 7 and 8, the plurality of grooves 5701, 5702, 5703, 5704, 5705, 5706, 5707, 5708, 5709, and 5710 may have a triangular cross-section. For example, referring to FIGS. 9 and 10, the plurality of grooves 5701, 5702, 5703, 5704, 5705, 5706, 5707, 5708, 5709, and 5710 may have a curved shape. For example, referring to FIGS. 9 and 10, the plurality of grooves 5701, 5702, 5703, 5704, 5705, 5706, 5707, 5708, 5709, and 5710 may have an arc shape. For example, referring to FIGS. 11 and 12, the plurality of grooves 5701, 5702, 5703, 5704, 5705, 5706, 5707, 5708, 5709, and 5710 may have a quadrangle cross-section. For example, FIGS. 11 and 12 illustrate that the plurality of grooves 5701, 5702, 5703, 5704, 5705, 5706, 5707, 5708, 5709, and 5710 has a rectangular cross-section, but the plurality of grooves 5701, 5702, 5703, 5704, 5705, 5706, 5707, 5708, 5709, and 5710 may have a square cross-section.

The drawings illustrate that the plurality of grooves 5701, 5702, 5703, 5704, 5705, 5706, 5707, 5708, 5709, and 5710 has a shape of becoming narrower as a distance from the light emitting surface 55 increases. (see FIGS. 5 to 10). However, embodiments of the present disclosure are not limited thereto, and as an example, the plurality of grooves 5701, 5702, 5703, 5704, 5705, 5706, 5707, 5708, 5709, and 5710 may have a shape of becoming wider as the distance from the light emitting surface 55 increases.

The drawings illustrate that the plurality of grooves 5701, 5702, 5703, 5704, 5705, 5706, 5707, 5708, 5709, and 5710 are spaced apart from each other by a predetermined interval (see FIGS. 5 to 12). However, embodiments of the present disclosure are not limited thereto. As an example, at least some of the plurality of grooves 5701, 5702, 5703, 5704, 5705, 5706, 5707, 5708, 5709, and 5710 may be provided to be in contact with each other. As an example, intervals between the plurality of grooves 5701, 5702, 5703, 5704, 5705, 5706, 5707, 5708, 5709, and 5710 may be different.

According to embodiments of the present disclosure, at least some of the plurality of grooves may be provided to have different shapes. For example, some of the plurality of grooves may have a quadrangle cross-sectional shape, and the other of the plurality of grooves may have a triangular cross-sectional shape. For example, the plurality of grooves may have different shapes, respectively. For example, examples of the plurality of grooves illustrated in FIGS. 5 to 12 may be combined with each other. Additionally, the groove part 57 may include various combinations of grooves other than the examples described above.

The QD layer 58 may be provided in the groove part 57. The QD layer 58 may be filled inside the groove part 57 (see FIGS. 5 to 12). The QD layer 58 may be provided not only in the groove part 57 but also on the light emitting surface 55. The QD layer 58 may be provided to cover the groove part 57 and the light emitting surface 55 (see FIGS. 6, 8, 10, and 12). The QD layer 58 may have a predetermined thickness t from the light emitting surface 55. For example, the QD layer 58 may include a first layer 581 provided in the groove part 57 and a second layer 582 provided to cover the light emitting surface 55 on the first layer 581. The second layer 582 may protrude from the light emitting surface 55. The second layer 582 may have the predetermined thickness t. For example, as QD ink is printed on the groove part 57 and/or the light emitting surface 55, the QD layer 58 may be formed.

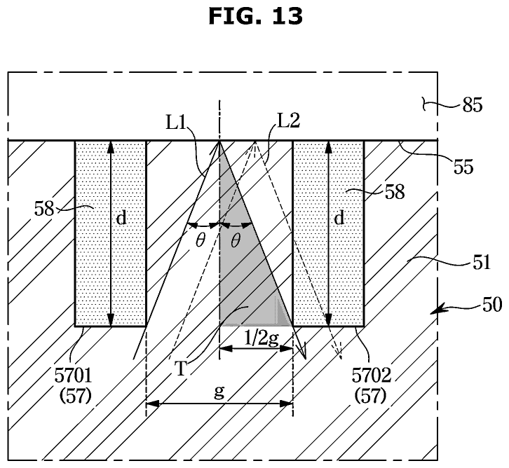

FIG. 13 is an enlarged cross-sectional view illustrating an example of the inorganic light emitting diode.

A relational formula regarding an interval between two adjacent grooves among the plurality of grooves may be derived with reference to FIG. 13. For convenience of explanation, an example of the groove 5701 and the groove 5702 will be described. The description of the groove 5701 and the groove 5702 may be applied to any two grooves adjacent to each other among the plurality of grooves.

The inorganic light emitting diode 50 may include the groove part 57. The groove part 57 may include the groove 5701 and the groove 5702 disposed adjacent to the groove 5701.

The light emitting surface 55 of the inorganic light emitting diode 50 may be provided to face a medium provided between the substrate 40 and the color filter 70 (e.g., in the space 85).

For example, optical clear resin (OCR) may be provided between the inorganic light emitting diode 50 and the color filter 70 (e.g., in the space 85). For example, the optical clear resin (OCR) may be provided between the substrate 40 and the color filter 70 (e.g., in the space 85). The optical clear resin (OCR) may improve visibility and image quality by increasing transmittance. The optical clear resin (OCR) may also be provided to protect the substrate. For example, air may be provided between the inorganic light emitting diode 50 and the color filter 70. For example, air may be provided between the substrate 40 and the color filter 70 (e.g., in the space 85). For example, a film having various optical functions may be provided between the inorganic light emitting diode 50 and the color filter 70 (e.g., in the space 85). However, embodiments of the present disclosure are not limited to the above-described examples, and various types of media may be provided depending on the configuration and/or arrangement of the display module 30.

A relational formula may be derived based on light L1 that is incident on the light emitting surface 55 between the groove 5701 and the groove 5702 and reflected from the light emitting surface 55.

FIG. 13 illustrates a state in which the groove 5701 and the groove 5702 are spaced apart by an interval g of the extent to which light L1 may pass the groove 5701 or the groove 5702. Based on the state illustrated in FIG. 13, a relational formula for the interval between the first groove and the second groove may be derived. In a case in which the interval between the first groove and the second groove is equal to or smaller than an interval derived by the relational formula, it may be understood that the light L1 may unconditionally pass through at least one from among the first groove and the second groove.

The light L1 generated in the active layer 53 may be incident on the light emitting surface 55 between the first groove and the second groove. In this case, an angle of incidence of the light L1 for being totally reflected may be larger than arcsin(n1/n2). Herein, n1 is a refractive index of the medium, and n2 is a refractive index of the inorganic light emitting diode 50.

Based on FIG. 13, a triangle T consisting of sides each formed by (i) an axis serving as a reference for reflection of the light L1, (ii) the light L1 reflected from the light emitting surface 55, and (iii) an imaginary line from the axis serving as a reference for reflection of the light L1 to the second groove is assumed. A length of the side of the triangle T formed by (i) the axis serving as a reference for reflection of the light L1 is d, and a distance of the triangle T (iii) from the axis serving as a reference for reflection of the light L1 to the second groove is g/2. Also, an angle θ of the triangle T between (i) the side formed by the axis serving as a reference for reflection of the light L1 and (ii) the side formed by the light L1 reflected from the light emitting surface 55 may be assumed as a critical angle arcsin(n1/n2). Applying trigonometric functions, tan θ is g/2d. That is, tan(arcsin(n1/n2)) is g/2d. In this case, g is 2d*tan(arcsin(n1/n2)).

Therefore, in a case in which the interval between the groove 5701 and the groove 5702 is equal to or smaller than 2d*tan(arcsin(n1/n2)), light incident on the light emitting surface 55 may pass through the groove 5701 and/or the groove 5702. Likewise, in the case in which the interval between the groove 5701 and the groove 5702 is equal to or smaller than 2d*tan(arcsin(n1/n2)), light incident on the light emitting surface 55 may pass through the QD layer 58 inside the groove 5701 and/or the QD layer 58 inside the groove 5702. For example, even when light generated in the active layer 53 (see L2) is incident on the light emitting surface 55 without passing through the groove 5701 and the groove 5702, the light (see L2) may be reflected from the light emitting surface 55 and pass through the groove 5701 and/or the groove 5702. The light (see light L2) may be color converted while passing through the QD layer 58 inside the groove 5701 and/or the QD layer 58 inside the groove 5702.

The light generated in the active layer 53 and reflected by the light emitting surface 55 may be provided to pass through at least one from among the groove 5701 and the groove 5702. In other words, the light generated in the active layer 53 and reflected from the light emitting surface 55 may pass through at least one from among the QD layer 58 inside the groove 5701 and the QD layer 58 inside the groove 5702. Accordingly, a rate at which light generated in the active layer 53 passes through the QD layer 58 may increase, and the color conversion efficiency of the inorganic light emitting diode 50 may be improved.

In summary, the groove 5701 and the groove 5702 may satisfy the following relational formula.

g≤2d*tan(arcsin(n1/n2)) (relational formula)
wherein g is the interval between the groove 5701 and the groove 5702, d is a depth of the groove 5701 and groove 5702, n1 is a refractive index of the medium toward which the light emitting surface 55 faces, and n2 is a refractive index of the inorganic light emitting diode 50.

For example, a case in which the medium is the optical clear resin (OCR) will be described. The refractive index n1 of the optical clear resin (OCR) may be substantially 1.5 to 1.6. In a case in which the inorganic light emitting diode 50 includes GaN, the refractive index n2 of the inorganic light emitting diode 50 may be substantially 2.4 to 2.7. In a case in which the refractive index n1 of the optical clear resin (OCR) is 1.6 and the refractive index n2 of the inorganic light emitting diode 50 is 2.4, the maximum value of 2*tan(arcsin(n1/n2)) may be calculated from the relational formula. A value of 2*tan(arcsin(1.6/2.4)) may be substantially 1.78885. Therefore, the interval between the groove 5701 and the groove 5702 may be smaller than substantially 1.79 times the depth d. The interval between two adjacent grooves among the plurality of grooves may be smaller than substantially 1.79 times the depth d.

For example, a case in which the medium is air will be described. The refractive index n1 of air may be substantially 1. In the case in which the inorganic light emitting diode 50 includes GaN, the refractive index n2 of the inorganic light emitting diode 50 may be substantially 2.4 to 2.7. In a case in which the refractive index n1 of air is 1 and the refractive index n2 of the inorganic light emitting diode 50 is 2.4, the maximum value of 2*tan(arcsin(n1/n2)) may be calculated from the relational formula. A value of 2*tan(arcsin(1/2.4)) may be substantially 0.916698. Therefore, the interval between the groove 5701 and the groove 5702 may be smaller than substantially 0.92 times the depth d. The interval between two adjacent grooves among the plurality of grooves may be smaller than substantially 0.92 times the depth d.

FIG. 13 illustrates an example in which the groove 5701 and the groove 5702 have a quadrangle cross-section and the dichroic filter 59 is not provided in the inorganic light emitting diode 50, but embodiments of the present disclosure are not limited thereto. The relational formula derived as described above may be applied to various embodiments. The relational formula derived as described above may also be applied to the examples of the inorganic light emitting diode 50 illustrated in FIGS. 5 to 12.

According to an embodiment, a display module 30 may include a substrate 40, an inorganic light emitting diode 50 mounted on the substrate, and a color filter 70 provided to correspond to the inorganic light emitting diode. The inorganic light emitting diode 50 may include an active layer 53 provided to generate light having a first color, a light emitting surface 55 provided to be spaced apart from the active layer, a groove part 57 having grooves continuously formed in the light emitting surface 55, and a quantum dot (QD) layer 58 provided in the groove part to convert light having the first color generated in the active layer into a second color. The color filter 70 may be provided to absorb light having the first color emitted from the inorganic light emitting diode.

The color filter 70 may be disposed to face the light emitting surface 55 of the inorganic light emitting diode 50.

The inorganic light emitting diode 50 may include a dichroic filter 59 provided to reflect light having the first color emitted through at least one from among the light emitting surface 55 and the QD layer 58.

The dichroic filter 59 may be provided to cover the light emitting surface 55 and the QD layer 58.

The QD layer 58 may be provided to cover the groove part 57 and the light emitting surface 55.

The groove part 57 may include a first groove and a second groove disposed adjacent to the first groove.

The light generated in the active layer 53 and reflected by the light emitting surface 55 may be provided to pass through at least one from among the first groove and the second groove.

Optical clear resin (OCR) may be provided between the inorganic light emitting diode and the color filter. The first groove and the second groove may satisfy the following relational formula: g≤2d*tan(arcsin(n1/n2)) (g: interval between the first groove and the second groove, d: depth of the first groove and second groove, n1: refractive index of the optical clear resin, and n2: refractive index of the inorganic light emitting diode).

The interval g between the first groove and the second groove may be provided to be smaller than 1.79 times the depth d.

Air may be provided between the inorganic light emitting diode and the color filter. The first groove and the second groove may satisfy the following relational formula: g≤2d*tan(arcsin(n1/n2)) (g: interval between the first groove and the second groove, d: depth of the first groove and second groove, n1: refractive index of the air, and n2: refractive index of the inorganic light emitting diode).

The interval g between the first groove and the second groove may be provided to be smaller than 0.92 times the depth d.

The inorganic light emitting diode may be a first inorganic light emitting diode (e.g., the red light emitting diode 50a) provided to convert blue light into red light, and the color filter may be a first color filter (e.g., the red filter 71) provided to absorb blue light emitted from the first inorganic light emitting diode. The display module 30 may include a second inorganic light emitting diode (e.g., the green light emitting diode 50b) provided to be spaced apart from the first inorganic light emitting diode and convert blue light into green light. The display module 30 may include a second color filter (e.g., the green filter 72) provided to correspond to the second inorganic light emitting diode and absorb blue light emitted from the second inorganic light emitting diode. The display module 30 may include a third inorganic light emitting diode (e.g., the blue light emitting diode 50c) provided to be spaced apart from the second inorganic light emitting diode and emit blue light. The display module 30 may include a third color filter (e.g., the blue filter 73) provided to correspond to the third inorganic light emitting diode and transmit blue light emitted from the third inorganic light emitting diode.

The display module 30 may include a black matrix 80 provided between the first color filter (e.g., the red filter 71) and the second color filter (e.g., the green filter 72) and between the second color filter (e.g., the green filter 72) and the third color filter (e.g., the blue filter 73).

The inorganic light emitting diode 50 may include contact electrodes (e.g., the first contact electrode 54a and the second contact electrode 54b) formed on an opposite side (e.g., the bottom surface 56) of the inorganic light emitting diode 50 from the light emitting surface 55, and the substrate 40 may include pad electrodes (e.g., the first pad electrode 45a and the second pad electrode 45b) corresponding to the contact electrodes.

The substrate 40 may include a substrate body 42, and a thin film transistor (TFT) layer 44 formed on the substrate body 42 to drive the inorganic light emitting diode 50.

According to an embodiment, an inorganic light emitting diode 50 may include a first semiconductor 51 provided to form a light emitting surface 55, a second semiconductor 52 provided to be spaced apart from the first semiconductor, an active layer 53 disposed between the first semiconductor and the second semiconductor to generate light, a groove part 57 having a plurality of grooves recessed in the light emitting surface, and a quantum dot (QD) layer 58 provided inside the groove part to convert a color of light generated in the active layer from a first color to a second color.

The inorganic light emitting diode 50 may include a dichroic filter 59 provided to cover the QD layer 58.

The dichroic filter 59 may be provided to reflect light having the first color emitted through at least one from among the light emitting surface 55 and the QD layer 58.

The QD layer 58 may be provided to cover the groove part 57 and the light emitting surface 55 and have a predetermined thickness t from the light emitting surface 55.

The plurality of grooves may be arranged to be spaced apart from each other, and two adjacent grooves among the plurality of grooves may satisfy the following relational formula: g≤2d*tan(arcsin(n1/n2)) (g: interval between the two neighboring grooves, d: depth of the groove, n1: refractive index of a medium toward which the light emitting surface faces, and n2: refractive index of the inorganic light emitting diode).

According to an embodiment, an inorganic light emitting diode 50 may include a first semiconductor comprising a light emitting surface, a second semiconductor spaced apart from the first semiconductor, an active layer between the first semiconductor and the second semiconductor and configured to generate light, a groove part comprising a plurality of grooves recessed in the light emitting surface, and a quantum dot (QD) layer inside the groove part. The QD layer may be configured to convert a color of the light generated by the active layer from a first color to a second color.

The inorganic light emitting diode 50 may include a dichroic filter configured to reflect light having the first color emitted through at least one from among the light emitting surface and the QD layer.

The dichroic filter may be on the light emitting surface and the QD layer.

The QD layer may be on the groove part and the light emitting surface.

The grooves may include a first groove and a second groove that is adjacent to the first groove.

According to embodiments of the present disclosure, light efficiency of an inorganic light emitting diode and a display module including the same can be improved.

According to embodiments of the present disclosure, color conversion efficiency of an inorganic light emitting diode and a display module including the same can be improved.

According to embodiments of the present disclosure, light loss of an inorganic light emitting diode and a display module including the same can be reduced.

Effects obtainable from embodiments the present disclosure are not limited to the effects mentioned above, and other effects not mentioned will be clearly understood by those skilled in the art from the present disclosure.

The foregoing has illustrated and described specific non-limiting example embodiments of the present disclosure. However, it should be understood by those of skilled in the art that embodiments of the present disclosure are not limited to the above-described example embodiments, and various changes and modifications may be made without departing from the spirit and scope of the present disclosure.

What is claimed is:

1. A display module comprising:
a substrate;
an inorganic light emitting diode on the substrate, the inorganic light emitting diode comprising:
an active layer configured to generate light having a first color;
a light emitting surface spaced apart from the active layer;
a groove part comprising grooves recessed in the light emitting surface; and
a quantum dot (QD) layer in the groove part and configured to convert the light having the first color generated in the active layer into a second color; and
a color filter corresponding to the inorganic light emitting diode and configured to absorb the light having the first color emitted from the inorganic light emitting diode.

2. The display module according to claim 1, wherein
the color filter faces the light emitting surface of the inorganic light emitting diode.

3. The display module according to claim 1, wherein the inorganic light emitting diode further comprises a dichroic filter configured to reflect light having the first color emitted through at least one from among the light emitting surface and the QD layer.

4. The display module according to claim 3, wherein
the dichroic filter is on the light emitting surface and the QD layer.

5. The display module according to claim 1, wherein
the QD layer is on the groove part and the light emitting surface.

6. The display module according to claim 1, wherein
the grooves comprise a first groove and a second groove that is adjacent to the first groove.

7. The display module according to claim 6, wherein
the light generated in the active layer and reflected by the light emitting surface passes through at least one from among the first groove and the second groove.

8. The display module according to claim 6, further comprising
an optical clear resin (OCR) between the inorganic light emitting diode and the color filter,
wherein the first groove and the second groove satisfies the following relational formula:
g≤2d*tan(arcsin(n1/n2))
wherein g is an interval between the first groove and the second groove, d is a depth of the first groove and the second groove, n1 is a refractive index of the OCR, and n2 is a refractive index of the inorganic light emitting diode.

9. The display module according to claim 8, wherein
the interval between the first groove and the second groove is smaller than 1.79 times the depth.

10. The display module according to claim 6, further comprising:
air between the inorganic light emitting diode and the color filter,
wherein the first groove and the second groove satisfies the following relational formula:
g≤2d*tan(arcsin(n1/n2)
wherein g is an interval between the first groove and the second groove, d is a depth of the first groove and the second groove, n1 is a refractive index of the air, and n2 is a refractive index of the inorganic light emitting diode.

11. The display module according to claim 10, wherein
the interval between the first groove and the second groove is smaller than 0.92 times the depth.

12. The display module according to claim 1, wherein
the inorganic light emitting diode is a first inorganic light emitting diode configured to convert blue light into red light,
the color filter is a first color filter configured to absorb blue light emitted from the first inorganic light emitting diode, and
the display module further comprises:
a second inorganic light emitting diode spaced apart from the first inorganic light emitting diode and configured to convert blue light into green light;
a second color filter corresponding to the second inorganic light emitting diode and configured to absorb blue light emitted from the second inorganic light emitting diode;
a third inorganic light emitting diode spaced apart from the second inorganic light emitting diode and configured to emit blue light; and
a third color filter corresponding to the third inorganic light emitting diode and configured to transmit the blue light emitted from the third inorganic light emitting diode.

13. The display module according to claim 12, further comprising
a black matrix between the first color filter and the second color filter and between the second color filter and the third color filter.

14. The display module according to claim 1, wherein
the inorganic light emitting diode further comprises contact electrodes formed on an opposite side of the inorganic light emitting diode from the light emitting surface, and
the substrate comprises pad electrodes corresponding to the contact electrodes.

15. The display module according to claim 1, wherein
the substrate comprises:
a substrate body; and
a thin film transistor (TFT) layer on the substrate body and configured to drive the inorganic light emitting diode.

16. An inorganic light emitting diode comprising:
a first semiconductor comprising a light emitting surface;
a second semiconductor spaced apart from the first semiconductor;
an active layer between the first semiconductor and the second semiconductor and configured to generate light;
a groove part comprising a plurality of grooves recessed in the light emitting surface; and
a quantum dot (QD) layer inside the groove part,
wherein the QD layer is configured to convert a color of the light generated by the active layer from a first color to a second color.

17. The inorganic light emitting diode according to claim 16, wherein
the inorganic light emitting diode further comprises a dichroic filter configured to reflect light having the first color emitted through at least one from among the light emitting surface and the QD layer.

18. The inorganic light emitting diode according to claim 17, wherein
the dichroic filter is on the light emitting surface and the QD layer.

19. The inorganic light emitting diode according to claim 16, wherein
the QD layer is on the groove part and the light emitting surface.

20. The inorganic light emitting diode according to claim 16, wherein
the grooves comprise a first groove and a second groove that is adjacent to the first groove.
